(19) United States
(12) Patent Application Publication
(10) Pub. No.: US 2026/0280508 A1
(43) Pub. Date: Sep. 17, 2026

(54) PRINTED FILTER

(71) Applicant: WNC Corporation, Hsinchu (TW)

(72) Inventor: Pei En HSU, Hsinchu (TW)

(21) Appl. No.: 19/256,338

(22) Filed: Jul. 1, 2025

(30) Foreign Application Priority Data
Mar. 17, 2025 (TW) 114109786

(51) Int. Cl. H03H 1/00; H01P 1/203

(52) U.S. Cl. CPC H03H 1/0007; H01P 1/20381; H03H 2001/0021

(57) ABSTRACT

A printed filter includes a first resonator, a second resonator, and a third resonator. The first resonator, the second resonator, and the third resonator each include an open-circuit segment and two short-circuit segments. Each short-circuit segment of the first resonator, the second resonator, and the third resonator are grounded. The two short-circuit segments of the respective first resonator and the second resonator are connected to form an L-shape. The open-circuit segment of the respective first resonator and the second resonator connects to its respective L-shape to form an arrow. The two short-circuit segments of the third resonator are connected to form a straight line. The open-circuit segment of the third resonator connects to the straight line of the third resonator to form a T-shape. One of the short-circuit segments of each of the first resonator and the second resonator is parallel to the straight line of the third resonator.

### RELATED APPLICATION

This application claims the benefit of priority to Taiwan Patent Application No. 114109786, filed on Mar. 17, 2025. The entire content of the above identified application is incorporated herein by reference.

### BACKGROUND

### Technical Field

The disclosure relates to a filter, particularly a printed filter.

### Description of Related Art

With the intensifying competition among communication products, reducing production costs has become an inevitable trend. The use of printed circuit board (PCB) technology to manufacture printed filters, such as microstrip filters, allows for smaller size and cost reduction, thus printed filters are widely applied in communication products. Printed band-pass filters can prevent interference between signals of different frequency bands in communication products. However, it is difficult for traditional printed band-pass filters to meet the near-1 GHz bandwidth required for high data rates in the UNII-1 to UNII-3 frequency bands used for Wi-Fi. Furthermore, when the frequency of the to-be-filtered signal approaches the passband frequency of the band-pass filter, the cutoff frequency of the band-pass filter needs to have a large attenuation slope to effectively suppress out-of-band frequency signals, thereby reducing interference from surrounding frequency signals. Traditional printed band-pass filters typically use higher-order designs to achieve greater bandwidth or increase the attenuation slope of the cutoff frequency, but this increases the circuit area. Under the trend of miniaturization in communication products, there is a need for a small-sized, high-bandwidth printed filter with a high attenuation slope to address the aforementioned problems.

### SUMMARY

In some embodiments, a printed filter is provided. The printed filter includes: a first resonator, a second resonator, and a third resonator. The first resonator, the second resonator, and the third resonator each include an open segment and two short segments, and each of the short segment of the first resonator, the second resonator, and the third resonator are grounded. The two short segments of the first resonator are connected to form an L-shape, and the two short segments of the second resonator are connected to form an L-shape. The open segment of the first resonator is connected to the L-shape of the first resonator to form an arrow, and the open segment of the second resonator is connected to the L-shape of the second resonator to form an arrow. The two short segments of the third resonator are connected to form a straight line, and the open segment of the third resonator is connected to the straight line of the third resonator to form a T-shape. One of the short segments of each of the first resonator and the second resonator are parallel to the straight line of the third resonator.

### BRIEF DESCRIPTION OF THE DRAWINGS

The described embodiments may be better understood by reference to the following description and the accompanying drawings.

FIG. 1 shows a schematic view of a printed filter according to an embodiment of the present disclosure.

FIGS. 2A, 2B, and 2C show schematic views of different forms of resonators according to embodiments of the present disclosure.

FIG. 3 shows a schematic view of a trisection structure according to an embodiment of the present disclosure.

FIG. 4A shows a theoretical S-parameter curve calculated based on the required filter specifications.

FIG. 4B shows the S-parameter values obtained by simulating the printed filter of the present disclosure using electromagnetic simulation software.

### DETAILED DESCRIPTION

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an” and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like. Moreover, the term “connect” described throughout the present disclosure indicates that there is a direct or indirect physical connection between two components, while the term “coupling” described throughout the present disclosure indicates that two components are physically separate, but conduct energy coupling through electric and/or magnetic field induction.

The present disclosure provides a small-sized, high-bandwidth printed filter with a high attenuation slope.

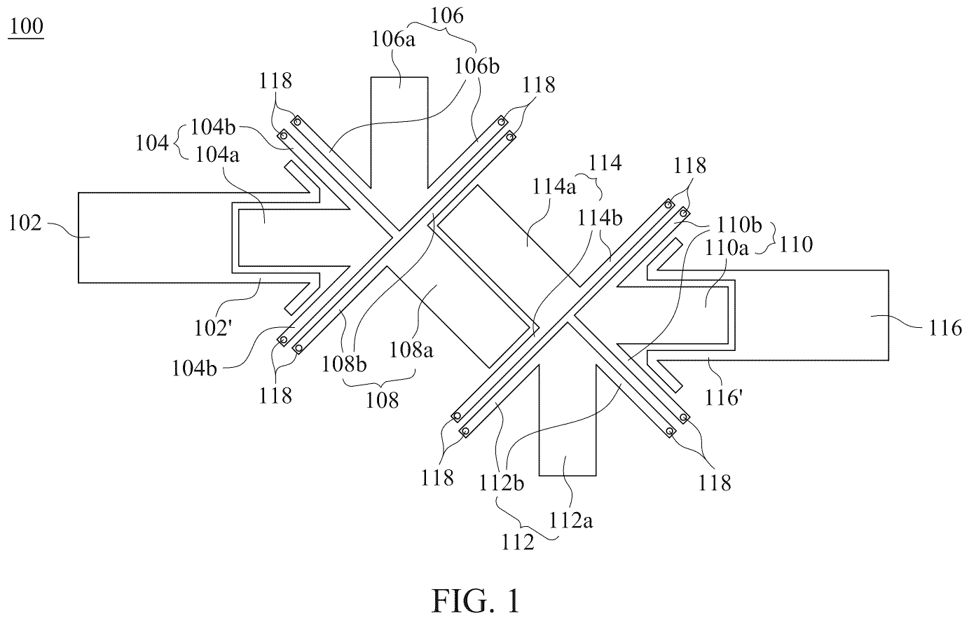

FIG. 1 shows a schematic view of a printed filter 100 according to an embodiment of the present disclosure. The printed filter 100 can be placed on a substrate (such as a PCB). The printed filter 100 can be a type of band-pass filter. The printed filter 100 includes a first resonator 104, a second resonator 106, a third resonator 108, a fourth resonator 110, a fifth resonator 112, and a sixth resonator 114. The first resonator 104 includes an open segment 104a and two short segments 104b, the second resonator 106 includes an open segment 106a and two short segments 106b, the third resonator 108 includes an open segment 108a and two short segments 108b, the fourth resonator 110 includes an open segment 110a and two short segments 110b, the fifth resonator 112 includes an open segment 112a and two short segments 112b, and the sixth resonator 114 includes an open segment 114a and two short segments 114b. Each short segment 104b, 106b, 108b, 110b, 112b, 114b can be grounded through respective vias 118. The first resonator 104, the second resonator 106, the third resonator 108 are configured to conduct energy coupling with each other via their respective two short segments 104b, 106b, 108b. The fourth resonator 110, the fifth resonator 112, and the sixth resonator 114 are configured to conduct energy coupling with each other via their respective two short segments 110b, 112b, 114b.

The printed filter 100 may also include an input segment 102 and an output segment 116. Signals transmitted from the input segment 102 to the output segment 116 travel through the printed filter 100, filtering out signals outside the high cutoff frequency and low cutoff frequency, allowing passband signals between the high cutoff frequency and low cutoff frequency to pass through, thus avoiding interference with other surrounding frequency signals. The input segment 102 is physically separate from the first resonator 104 and configured to conduct energy coupling with the first resonator 104. The output segment 116 is physically separate from the fourth resonator 110 and configured to conduct energy coupling with the fourth resonator 110. The input segment 102 may include a branch segment 102′, and the shape of the branch segment 102′ can be adapted to the first resonator 104, allowing the input segment 102 to surround at least a portion of the open segment 104a of the first resonator 104 to increase coupling amount. Additionally, due to the shape design, a portion of the branch segment 102′ of the input segment 102 can couple with the two short segments 104b of the first resonator 104 to increase coupling amount. The output segment 116 may include a branch segment 116′, and the shape of the branch segment 116′ can be adapted to the fourth resonator 110, allowing the output segment 116 to surround at least a portion of the open segment 110a of the fourth resonator 110 to increase coupling amount. Additionally, due to the shape design, a portion of the branch segment 116′ of the output segment 116 can couple with the two short segments 110b of the fourth resonator 110 to increase coupling.

The first resonator 104, the second resonator 106, the third resonator 108, the fourth resonator 110, the fifth resonator 112, and the sixth resonator 114 are physically separate from each other. One of the short segments 104b, 106b, 110b, 112b of each of the first resonator 104, the second resonator 106, the fourth resonator 110, and the fifth resonator 112 are parallel to the straight line formed by the short segments 108b, 114b of each of the third resonator 108 and the sixth resonator 114.

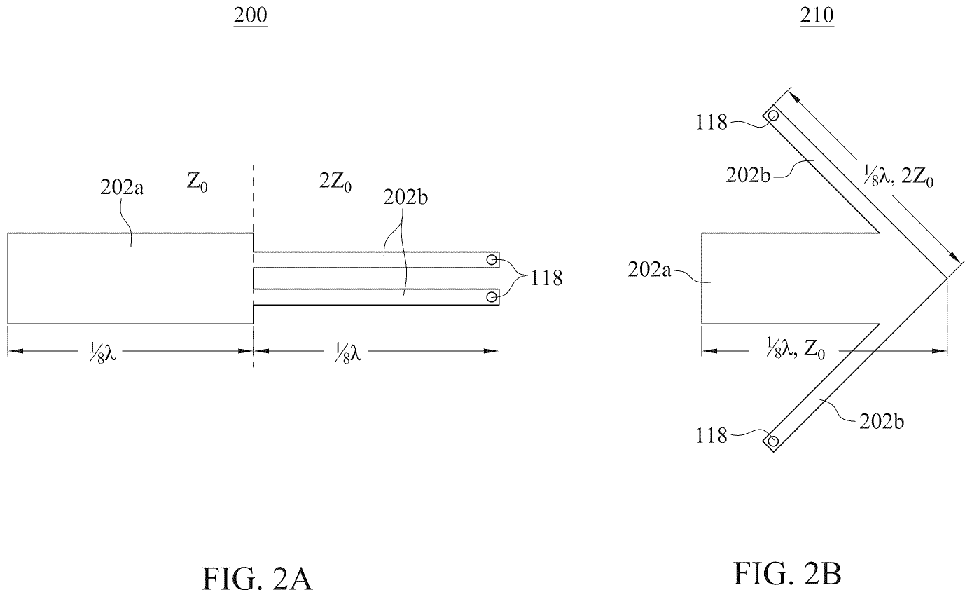

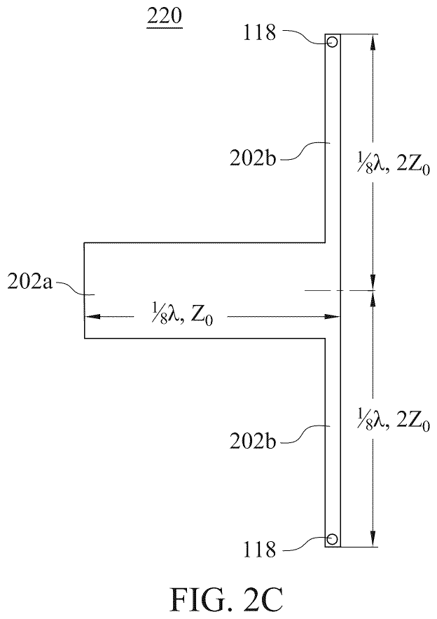

The principles of the printed filter 100 will be described below in accordance with FIG. 2A, FIG. 2B, FIG. 2C, and FIG. 3. FIG. 2A, FIG. 2B, FIG. 2C, and FIG. 3 can be referenced alongside FIG. 1. FIG. 2A shows a resonator 200, which includes an open segment 202a and two short segments 202b, and each short segment 202b is grounded through respective vias 118. The resonator 200 can have a resonant frequency, wherein the lengths of the open segment 202a and the short segments 202b can be designed according to the wavelength corresponding to the resonant frequency. For example, the resonator 200 can be a quarter-wavelength resonator, wherein the lengths of the open segment 202a and the short segments 202b are each approximately one-eighth of the wavelength. The impedance of the open segment 202a is about Z₀, while the impedance of the short segments 202b is about 2Z₀, meaning each short segment 202b has an impedance approximately twice the value of the open segment 202a. The two short segments 202b in FIG. 2A are configured in parallel, thus the equivalent impedance of the two parallel short segments 202b is Z₀, making the resonator 200 a uniform impedance quarter-wavelength resonator.

FIG. 2B shows a resonator 210, which also includes an open segment 202a and two short segments 202b, and the lengths and impedances of the open segment 202a and the short segments 202b are the same as described in FIG. 2A; however, the resonator 210 has an arrow shape that differs from the resonator 200 in FIG. 2A. In FIG. 2B, the two short segments 202b are connected to form an L-shape, and the open segment 202a is connected to the L-shape to form an arrow. This arrow shape increases the coupling flexibility between resonators. The L-shape formed by the two short segments 202b in FIG. 2B has an angle of approximately 90 degrees, but in some other embodiments, the L-shape can have other angles. Additionally, FIG. 2B shows the open segment 202a to have a generally rectangular shape, but the open segment 202a can be configured as other shapes, such as a stepped shape or other shapes. The aforementioned shape variations of the short segments 202b and the open segment 202a can still be considered as forming an arrow. The arrow-shaped resonator 210 shown in FIG. 2B can correspond to the first resonator 104, the second resonator 106, the fourth resonator 110, and the fifth resonator 112 in FIG. 1. However, it should be noted that the lengths and widths of the open segments 104a, 106a, 110a, 112a and the short segments 104b, 106b, 110b, 112b of the first resonator 104, the second resonator 106, the fourth resonator 110, and the fifth resonator 112 may vary due to adjustments. For example, the length or width of the open segment 104a of the first resonator 104 may differ from that of the open segment 106a of the second resonator 106. As another example, the two short segments 104b of the first resonator 104 may have the same length, and the two short segments 106b of the second resonator 106 may have the same length, but the length of the two short segments 104b of the first resonator 104 may differ from the length of the two short segments 106b of the second resonator 106. For conciseness, other variations in lengths and widths are not exhaustively listed herein.

FIG. 2C shows a resonator 220, which also includes an open segment 202a and two short segments 202b, and the lengths and impedances of the open segment 202a and the short segments 202b are the same as described in FIG. 2A; however, the resonator 220 has a T-shape that differs from the resonator 200 in FIG. 2A. In FIG. 2C, the two short segments 202b are connected to form a straight line, and the open segment 202a is connected to the straight line to form the T-shape. This T-shape also increases the coupling flexibility between resonators. FIG. 2C shows the open segment 202a to have a generally rectangular shape, but it can be configured as other shapes, such as a stepped shape or other shapes. The T-shaped resonator 220 shown in FIG. 2C can correspond to the third resonator 108 and the sixth resonator 114 in FIG. 1. However, it should be noted that the lengths and widths of the open segments 108a, 114a and the short segments 108b, 114b of the third resonator 108 and the sixth resonator 114 may vary due to adjustments. For example, the length or width of the open segment 108a of the third resonator 108 may differ from that of the open segment 114a of the sixth resonator 114. As another example, the two short segments 108b of the third resonator 108 may have the same length, the two short segments 114b of the sixth resonator 114 may have the same length, but the length of the two short segments 108b of the third resonator 108 may differ from the length of the two short segments 114b of the sixth resonator 114. For conciseness, other variations in lengths and widths are not exhaustively listed herein.

In some variations, the lengths of the open segment 202a and the short segments 202b in the same resonator 210, 220 shown in FIGS. 2B and 2C may differ. In other words, although it was previously mentioned that the lengths of the open segment 202a and the short segments 202b are approximately one-eighth of the wavelength, in practice, the lengths of the open segment 202a and/or the short segments 202b may be altered to adjust the characteristics of the filter, resulting in different lengths for the open segment 202a and the short segments 202b. The present disclosure encompasses such variations.

Furthermore, the lengths and widths of the open segments (e.g., open segments 104a, 106a, 110a, 112a) and the short segments (e.g., short segments 104b, 106b, 110b, 112b) of the arrow-shaped resonators (e.g., first resonator 104, second resonator 106, fourth resonator 110, and fifth resonator 112) may differ from the lengths and widths of the open segments (e.g., open segments 108a, 114a) and the short segments (e.g., short segments 108b, 114b) of the T-shaped resonators (e.g., third resonator 108 and sixth resonator 114).

FIG. 3 shows a trisection structure 300 formed by two arrow-shaped resonators 302, 304 and one T-shaped resonator 306. One trisection structure 300 itself already has filtering effects, but multiple trisection structures 300 can be cascaded to enhance filtering characteristics. FIG. 3 can be referenced alongside FIG. 1. FIG. 1 can be viewed as two cascaded trisection structures 300, wherein the resonators 302, 304 in FIG. 3 can correspond to the first resonator 104 and the second resonator 106, or correspond to the fourth resonator 110 and the fifth resonator 112 in FIG. 1. Additionally, the resonator 306 in FIG. 3 can correspond to the third resonator 108 or the sixth resonator 114 in FIG. 1. Referring to FIG. 3, the resonator 302 includes an open segment 302a and two short segments 302b, the resonator 304 includes an open segment 304a and two short segments 304b, and the resonator 306 includes an open segment 306a and two short segments 306b. One of the short segments 302b, 304b of each of the resonators 302 and 304 can be parallel to the straight line formed by the two short segments 306b of the resonator 306. The resonators 302, 304, 306 are physically separate from each other but can conduct energy coupling, wherein the energy coupling in FIG. 3 is indicated as coupling C1, coupling C2, and coupling C3. In the embodiment of FIG. 3, the coupling C1 occurs between the resonators 302 and 304 via the short segments 302b and 304b; coupling C2 occurs between the resonators 304 and 306 via the short segments 304b and 306b; and coupling C3 occurs between the resonators 306 and 302 via the short segments 306b and 302b. There is a first gap G1 between the resonators 302 and 304, a second gap G2 between the resonators 304 and 306, and a third gap G3 between the resonators 302 and 306. The minimum value of the first gap G1 may be the same as or different from the minimum value of the second gap G2; the minimum value of the first gap G1 may be the same as or different from the minimum value of the third gap G3; and the minimum value of the second gap G2 may be the same as or different from the minimum value of the third gap G3. For example, in some embodiments, the minimum value of the third gap G3 may be greater than the minimum values of the first gap G1 or the second gap G2. The sizes of the first gap G1, the second gap G2, and the third gap G3 may directly or indirectly affect the following characteristics of the trisection structure 300: the coupling amount of coupling C1-C3 between the conductors, bandwidth, insertion loss, stop-band attenuation, transmission zeros, etc. The lengths and widths of the open segments 302a, 304a, 306a and the short segments 302b, 304b, 306b will also affect the characteristics of the trisection structure 300, such as resonant frequency, coupling amount, etc. The aforementioned theoretical examples are for reference only; in practice, the various characteristics of the filter may be interrelated, such that the aforementioned characteristics may all be influenced by the lengths and widths of each resonator and the gaps between resonators.

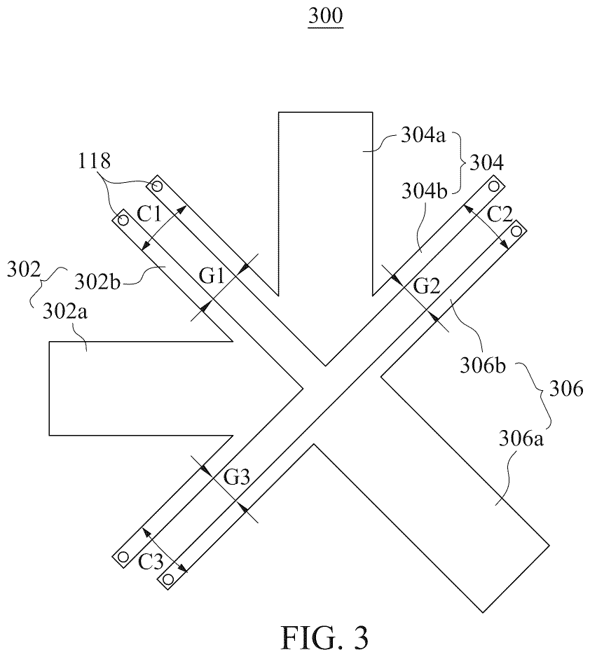

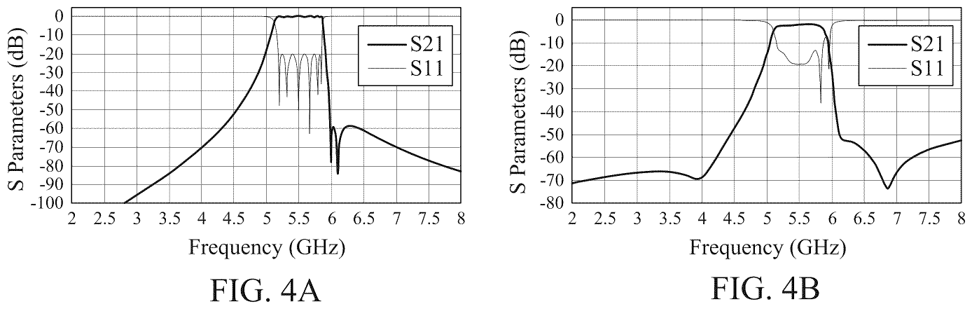

The trisection structure 300 shown in FIG. 3 can generate a transmission zero in the out-of-band region. The printed filter 100 shown in FIG. 1 is formed by cascading two trisection structures 300, which can generate two transmission zeros in the out-of-band region to provide sufficient out-of-band suppression. The transmission zeros will be further described in subsequent FIG. 4A. The cascading of two trisection structures 300 can be achieved through coupling the open segments of the resonators. For example, as shown in FIG. 1, the third resonator 108 and the sixth resonator 114 are configured to couple via their respective open segments 108a and 114a to cascade the two trisection structures.

FIG. 4A shows a theoretical S-parameter curve calculated based on the required filter specifications. FIG. 4B shows the S-parameter values obtained by simulating the printed filter 100 of the present disclosure using electromagnetic simulation software. The results obtained in FIG. 4B should ideally resemble the curve in FIG. 4A. S-parameters are often used to evaluate the transmission and reflection characteristics of one or more ports in a circuit. The S-parameters shown in FIG. 4A and FIG. 4B include S11 parameter and S21 parameter, where S11 parameter can be used to evaluate the reflection characteristics of signals at the input segment 102, and S21 parameter can be used to evaluate the transmission characteristics of signals from the input segment 102 to the output segment 116.

As shown in FIG. 4A, it is desired to design a band-pass filter that can produce a passband in the frequency range of approximately 5180 MHz to 5835 MHz, allowing passband signals to pass through while filtering out signals outside the passband. This design can meet the bandwidth requirements for Wi-Fi in the UNII-1 to UNII-3 frequency bands. In the passband between 5180 MHz and 5835 MHz shown in FIG. 4A, S11 parameter is approximately −20 dB to −50 dB, and S21 parameter is approximately 0 dB, indicating minimal reflection of signals at the input segment 102, and most signals can be transmitted from the input segment 102 to the output segment 116 without attenuation. Regarding out-of-band characteristics, since it is desired to have effective filtering of signals above 6 GHz while allowing signals between 5180 MHz and 5835 MHz to pass through, generating high attenuation slope characteristics in the narrow frequency band between 5835 MHz and 6 GHz will be one of the challenges in the design of the band-pass filter. As previously mentioned, cascading two trisection structures 300 can generate two transmission zeros, corresponding to approximately 5980 MHz and 6090 MHz in the S21 parameter in FIG. 4A. These two transmission zeros can enhance filtering effects near 6 GHz, resulting in approximately 40 dB of out-of-band attenuation at approximately 5900 MHz.

FIG. 4B shows the S-parameter values obtained by simulating the printed filter 100 of the present disclosure using electromagnetic simulation software. FIG. 4B shows that the bandwidth of the passband is close to 1 GHz, and an out-of-band attenuation of approximately 45 dB can be achieved at 6105 MHz. Although the results shown in FIG. 4B do not clearly display the two transmission zeros near 6 GHz as in FIG. 4A, the out-of-band suppression effect still exists. The S-parameters shown in FIG. 4B can be used for reference, but the actual S-parameters measured for the printed filter 100 will be influenced by the sizes of each resonator and the gaps between the resonators. Nevertheless, the printed filter 100 of the present disclosure can achieve the effects of a small size, high bandwidth, and high attenuation slope.

The embodiments were chosen and described in order to explain the principles of the present disclosure and their practical applications. Alternative embodiments will become apparent to those skilled in the art to which the present disclosure pertains without departing from its spirit and scope.

What is claimed is:

1. A printed filter comprising:
a first resonator;
a second resonator; and
a third resonator;
wherein:
the first resonator, the second resonator, and the third resonator each include an open segment and two short segments, and each of the short segment of the first resonator, the second resonator, and the third resonator are grounded;
the two short segments of the first resonator are connected to form an L-shape, and the two short segments of the second resonator are connected to form an L-shape;
the open segment of the first resonator is connected to the L-shape of the first resonator to form an arrow, and the open segment of the second resonator is connected to the L-shape of the second resonator to form an arrow;
the two short segments of the third resonator are connected to form a straight line;
the open segment of the third resonator is connected to the straight line of the third resonator to form a T-shape; and
one of the short segments of each of the first resonator and the second resonator are parallel to the straight line of the third resonator.

2. The printed filter according to claim 1, further comprising:
a fourth resonator;
a fifth resonator; and
a sixth resonator;
wherein:
the fourth resonator, the fifth resonator, and the sixth resonator each include an open segment and two short segments, and each short segment of the fourth resonator, the fifth resonator, and the sixth resonator grounded;
the two short segments of the fourth resonator are connected to form an L-shape, and the two short segments of the fifth resonator are connected to form an L-shape;
the open segment of the fourth resonator is connected to the L-shape of the fourth resonator to form an arrow, and the open segment of the fifth resonator is connected to the L-shape of the fifth resonator to form an arrow;
the two short segments of the sixth resonator are connected to form a straight line;
the open segment of the sixth resonator is connected to the straight line of the sixth resonator to form a T-shape; and
one of the short segments of each of the first resonator, the second resonator, the fourth resonator, and the fifth resonator are parallel to the straight line of the third resonator and the straight line of the sixth resonator.

3. The printed filter according to claim 2, wherein the first resonator, the second resonator, the third resonator, the fourth resonator, the fifth resonator, and the sixth resonator are physically separate from each other.

4. The printed filter according to claim 1, wherein the first resonator, the second resonator, and the third resonator are configured to conduct energy coupling with each other via their respective two short segments.

5. The printed filter according to claim 2, wherein the fourth resonator, the fifth resonator, and the sixth resonator are configured to conduct energy coupling with each other via their respective two short segments.

6. The printed filter according to claim 2, wherein the third resonator and the sixth resonator are configured to conduct energy coupling via their respective open segments.

7. The printed filter according to claim 1, wherein the two short segments of the first resonator have a same length, the two short segments of the second resonator have a same length, and the length of the two short segments of the first resonator differs from the length of the two short segments of the second resonator.

8. The printed filter according to claim 2, wherein the open segment of the third resonator has a length, the open segment of the sixth resonator has a length, and the length of the open segment of the third resonator differs from the length of the open segment of the sixth resonator.

9. The printed filter according to claim 2, wherein the open segment of the third resonator has a width, the open segment of the sixth resonator has a width, and the width of the open segment of the third resonator differs from the width of the open segment of the sixth resonator.

10. The printed filter according to claim 1, wherein there is a first gap between the first resonator and the second resonator, there is a second gap between the second resonator and the third resonator, and there is a third gap between the first resonator and the third resonator, wherein:
a minimum value of the first gap differs from a minimum value of the second gap;
the minimum value of the first gap differs from a minimum value of the third gap; or
the minimum value of the second gap differs from the minimum value of the third gap.

11. The printed filter according to claim 1, wherein the L-shape has an angle of 90 degrees.

12. The printed filter according to claim 1, wherein the first resonator has a resonant frequency, the open segment and the two short segments of the first resonator have a same length, and the length is equal to one-eighth of a wavelength corresponding to the resonant frequency.

13. The printed filter according to claim 2, further comprising:
an input segment; and
an output segment;
wherein the input segment is physically separate from the first resonator, and the input segment is configured to conduct energy coupling with the first resonator; and
the output segment is physically separate from the fourth resonator, and the output segment is configured to conduct energy coupling with the fourth resonator.

14. The printed filter according to claim 13, wherein the input segment surrounds at least a portion of the open segment of the first resonator, and the output segment surrounds at least a portion of the open segment of the fourth resonator.

15. The printed filter according to claim 14, wherein the input segment and the output segment each include a branch segment, a portion of the branch segment of the input segment is configured to conduct energy coupling with the two short segments of the first resonator, and a portion of the branch segment of the output segment is configured to conduct energy coupling with the two short segments of the fourth resonator.

16. The printed filter according to claim 1, wherein, for the first resonator, the second resonator or the third resonator, an impedance of each of the two short segments is twice the value of an impedance of the open segment.
